(19) United States
(12) Patent Application Publication
(10) Pub. No.: US 2025/0279384 A1
(43) Pub. Date: Sep. 4, 2025

(54) METHODS AND APPARATUS USING POLYMER MATERIAL TO FILL GAPS BETWEEN SEMICONDUCTOR DIES

(71) Applicant: Intel Corporation, Santa Clara, CA (US)

(72) Inventors: Hongxia Feng, Chandler, AZ (US); Trianggono Widodo, Hillsboro, OR (US); Radha Malini Gowri Muddu, Portland, OR (US); Elizabeth Nofen, Phoenix, AZ (US); Mohit Gupta, Chandler, AZ (US); Jose Fernando Waimin Almendares, Gilbert, AZ (US); Dingying Xu, Chandler, AZ (US); Ashay Dani, Chandler, AZ (US); Leonel Arana, Phoenix, AZ (US); Xavier F. Brun, Hillsboro, OR (US); Houri Johari-Galle, Los Gatos, CA (US); Sairam Agraharam, Chandler, AZ (US); Nitin Deshpande, Chandler, AZ (US)

(21) Appl. No.: 18/592,028

(22) Filed: Feb. 29, 2024

(51) Int. Cl. H01L 23/00; H01L 21/02; H01L 21/321; H01L 23/498; H01L 25/065

(52) U.S. Cl. CPC H01L 24/29; H01L 21/02065; H01L 21/3212; H01L 23/49816; H01L 23/49838; H01L 25/0652; H01L 2224/29021; H01L 2224/2919; H01L 2924/1431; H01L 2924/1434; H01L 2924/15311

(57) ABSTRACT

Methods and apparatus using polymer material to fill gaps between semiconductor dies are disclosed. An example apparatus comprises a semiconductor substrate, a semiconductor die positioned on the semiconductor substrate, and a polymer material in contact with a side of the semiconductor die, the polymer material extending from a first surface of the semiconductor die towards a second surface of the semiconductor die, the first surface of the semiconductor die facing towards the semiconductor substrate and the second surface of the semiconductor die facing away from the semiconductor substrate.

### FIELD OF THE DISCLOSURE

This disclosure relates generally to semiconductor dies and, more particularly, to methods and apparatus using polymer material to fill gaps between semiconductor dies.

### BACKGROUND

The rapid speed of data transmission within computation, storage and communication infrastructures is pushing the speed boundary of traditional copper-based electrical interconnects in integrated circuit packages. Additionally, with the increasing functionality of circuitry and increasing density of semiconductor devices, physically positioning a sufficient number of interconnects on an exterior surface of a die has become increasingly difficult. Die stacking allows for multi-chip package structures that enable significant performance leaps in computing capability and memory/processor integration. The multi-chip package structures, allowed by die stacking, allow for increased speed in data transmission, as die stacking allows for more interconnects on the exterior surface of the die.

### BRIEF DESCRIPTION OF THE DRAWINGS

FIG. 1 illustrates an example integrated circuit (IC) package that is electrically coupled to a circuit board.

FIG. 2 illustrates an example semiconductor package including example polymer material.

FIG. 3 is a table including physical properties associated with the example polymer material of FIG. 2.

FIG. 4 is a flowchart representative of an example method of manufacturing the example semiconductor package of FIG. 2 and an example semiconductor package of FIG. 5E in accordance with example techniques described in connection with FIGS. 5A-6C.

FIGS. 5A-5E illustrate various stages in an example process of fabrication of the example semiconductor package of FIG. 5E.

FIGS. 5A-5D and 6A-6C illustrate various stages in an example process of fabrication of the example semiconductor package of FIG. 2.

FIG. 7 is a top view of a wafer including dies that may be included in an IC package constructed in accordance with teachings disclosed herein.

FIG. 8 is a cross-sectional side view of an IC device that may be included in an IC package constructed in accordance with teachings disclosed herein.

FIG. 9 is a cross-sectional side view of an IC device assembly that may include an IC package constructed in accordance with teachings disclosed herein.

FIG. 10 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

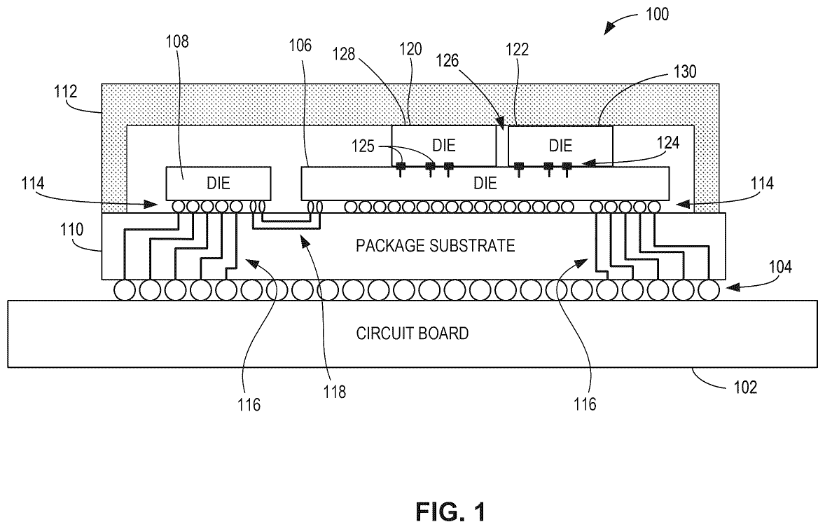

FIG. 1 illustrates an example integrated circuit (IC) package 100 that is electrically coupled to a circuit board 102. In some examples, the IC package 100 is electrically coupled to the circuit board 102 by first electrical connections 104. The first electrical connections 104 may include pins, pads, bumps, and/or balls to enable the electrical coupling of the IC package 100 to the circuit board 102. In this example, the IC package 100 includes two semiconductor dies 106, 108 (e.g., two silicon dies) that are mounted to a package substrate 110 and enclosed by a mold compound or package lid 112.

As shown in the example of FIG. 1, each of the dies 106, 108 is electrically and mechanically coupled to the package substrate 110 via second electrical connections 114. The second electrical connections 114 may include pins, pads, balls, and/or bumps. The second electrical connections 114 between the dies 106, 108 and the package substrate 110 are sometimes referred to as first level interconnects. By contrast, the first electrical connections 104 between the IC package 100 and the circuit board 102 are sometimes referred to as second level interconnects. In some examples, one or both of the dies 106, 108 may be stacked on top of one or more other dies and/or an interposer. In such examples, the dies 106, 108 are coupled to the underlying die and/or interposer through a first set of first level interconnects and the underlying die and/or interposer may be connected to the package substrate 110 via a separate set of first level interconnects associated with the underlying die and/or interposer.

As shown in the illustrated example, the package substrate 110 includes first electrical traces and/or routing 116 that electrically connects the first electrical connections 104 with the second electrical connections 114, thereby enabling the electrical coupling of the first and/or second dies 106, 108 with the circuit board 102. Further, in some examples, the package substrate 110 includes second electrical traces and/or routing 118 that electrically connect different ones of the first electrical connections 104 associated with the first and second dies 106, 108, thereby enabling the electrical coupling of the first and second dies 106, 108.

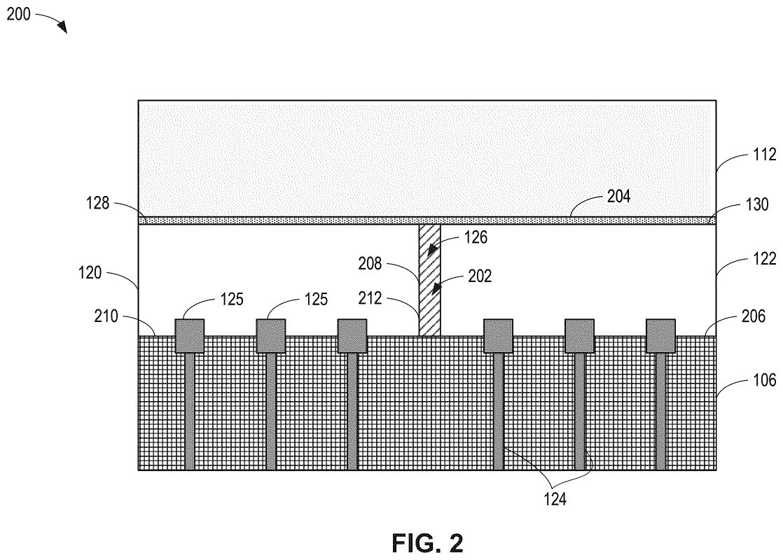

The IC package 100 includes a third semiconductor die 120 that is hybrid bonded (e.g., adjacent, attached, connected, etc.) to the first semiconductor die 106 and a fourth semiconductor die 122 that is hybrid bonded to the first semiconductor die 106. While the example IC package 100 of FIG. 1 includes four dies 106, 108, 120, 122 in other examples, the IC package 100 may have three or fewer dies or more than four dies. FIG. 1 is a generic package that illustrates dies that can be stacked (e.g., hybrid bonded). An example implementation of die stacking of FIG. 1 is illustrated in FIG. 2.

Hybrid bonding is a process that requires at least two surfaces that are both flat and clean (e.g., a first flat and clean surface to be hybrid bonded to a second flat and clean surface). Hybrid bonding has been used to connect various combinations of wafers, chips, dies, interposers and/or other semiconductor substrates. In some examples, the hybrid bonding is performed to connect a first semiconductor substrate and a second semiconductor substrate (e.g., the die 106 and the die 120) via example embedded interconnects 124. More particularly, in some examples, first portions of the interconnects 124 are provided in the bottom substrate (e.g., the first die 106 in FIG. 1) and second (corresponding) portions of the interconnects 124 are provided in the upper die (e.g., the third die 120). Both portions of the interconnects 124 bonding pads 125 that are exposed on the flat clean surfaces at the interface of the two substrates so that when the surfaces are mated together and heat is applied, the abutting bonding pads 125 become directly attached through fusion bonding. In some examples, hybrid bonding between dies is performed before the dies have been singulated (e.g., wafer-to-wafer bonding) or after singulation of at least the upper dies (e.g., chip-to-wafer bonding). Often, after dies (or wafers) have been hybrid bonded to an underlying semiconductor substrate, the dies may undergo a thinning process to remove excess semiconductor material. The thinning process reduces the overall size of packages and also may provide clean, flat surfaces 128, 130 to facilitate the attachment of a package lid (e.g., the lid 112), which may also be achieved through hybrid bonding. However, the friction induced by the thinning process may cause the dies 120, 120 to crack and/or chip (e.g., along the surfaces 128, 130, at the corners of the dies 120, 122, along the lateral edges of the dies 120, 122, etc.).

After thinning, an oxide material (e.g., silicon dioxide, silicon nitride, dielectric material, inorganic material, etc.) is typically used to fill a gap 126 between the dies 106, 120, 122 to enhance (e.g., stabilize, strengthen, etc.) the bond between the dies 106, 120, 122. In some examples, the gap 126 (e.g., distance) between the dies 120, 122 may be hundreds of micrometers (μm) (e.g., 0-300 μm). An amount of the oxide material may fill the gap 126 and overfill the gap 126 with additional material (e.g., an over-burden) that covers at least a portion of the surface 128 of the die 120 and the surface 130 of the die 122. Then, during a chemical-mechanical planarization (CMP) process, the overfill oxide material is removed such that the oxide material is substantially flush (e.g., within 100 nanometers (nm) of linear offset and within 5 degrees) (°) of angular offset) with the surfaces 128, 130 of the dies 120, 122.

This process of depositing the oxide material, overfilling the oxide material, and removing the oxide material from the surfaces 128, 130 is costly and time consuming. Further, any cracks and/or chips on the underlying dies 120, 122 due to thinning may cause misalignment between subsequent layers and/or components (e.g., the package lid 112) of the semiconductor substrate. Such misalignment may be aggravated by wafer warpage induced by film stress at the interface between the oxide material and the dies 106, 120, 122. In some examples, misalignment between the dies 106, 120, 122 and the package lid 112 may impede the integrity of the bond between the package lid 112 and the dies 120, 122. Further, fit tolerances between components are critical for device performance, so an improperly bonded package lid 112 may impair the performance of the IC package 100.

One solution to mitigate die cracking in hybrid bonding applications include the use of epoxy molding compounds (EMCs). However, EMCs have a low glass transition temperature (Tg) (e.g., <200 Celsius (C)) that may not be suitable for subsequent high temperature processes (e.g., fusion bonding to attach a package lid). As such, additional bonding films may be needed for use with EMCs to stabilize a bond between a die and a package lid. Further, EMCs may still be susceptible to film stress and/or warpage.

Examples disclosed herein fill the gaps between semiconductor dies (e.g., the dies 120, 122) of a semiconductor package with a polymer material (e.g., organic material). In some examples, the polymer material is a polyimide (e.g., a polymer containing an imide group bound to nitrogen). Thus, in some examples, the polymer material includes nitrogen, oxygen, and carbon, and may also include other elements (e.g., hydrogen). In disclosed examples, the liquid form of such a polymer material can conform directly to the surfaces of the dies (e.g., the dies 120, 122) and fill the gap without first needing to thin the dies. That is, known techniques based on an oxide fill typically cannot reliably deposit the oxide all the way down to the bottom of the depth of the gap 126 defined by a full thickness of the dies 120, 122, which is why the dies first undergo a thinning process. Further, applying a polymer material between the dies before the thinning process provides structural integrity to the assembly to reduce (e.g., avoid) any cracks and/or chips caused when the dies (along with the polymer material) undergo a thinning process. Further, disclosed examples utilize an example polymer material with a high Tg (e.g., greater than 250 C) to withstand the high temperatures associated with subsequent processing (e.g., the fusion bonding with a package lid).

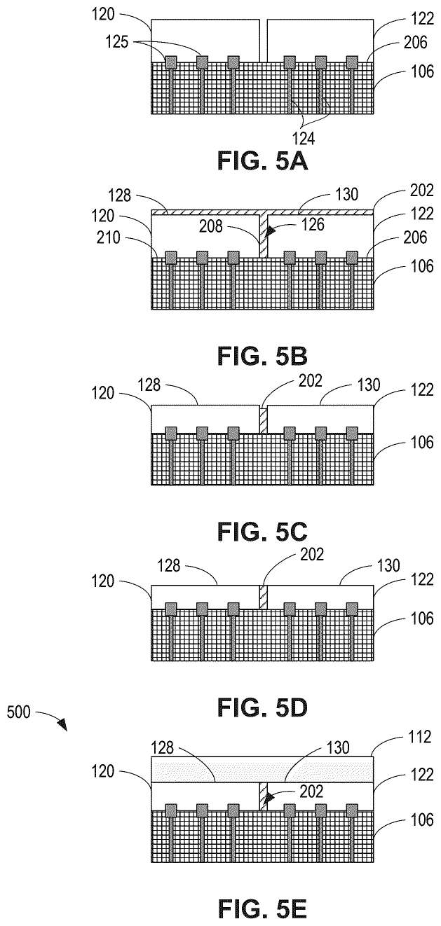

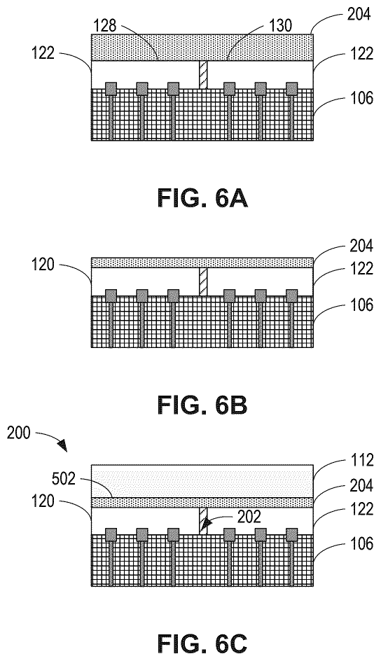

FIG. 2 is a cross sectional view of an example semiconductor package 200. The example semiconductor package 200 of FIG. 2 may be manufactured according to the example manufacturing process illustrated in stages in FIGS. 5A-5D and 6A-6C. In some examples, the semiconductor package 200 is a standalone package. In other examples, the semiconductor package 200 is included in and/or a part of a larger package. For instance, in the illustrated example, the semiconductor package 200 corresponds to a portion of the example package 100 of FIG. 1. Thus, the example semiconductor package 200 includes the dies 106, 120, 122, the package lid 112, and the example embedded interconnects 124 (including the bonding pads 125). Further, as shown in FIG. 2, the example semiconductor package 200 includes an example polymer material 202, and an example dielectric layer 204. The example dies 120, 122 may be hybrid bonded to the die 106 or any other semiconductor substrate and/or interposer. Hereinafter, the example die 106 may be referred to as an example semiconductor substrate 106. The example dies 120, 122 are positioned on (e.g., bonded to) an example surface 206 of the semiconductor substrate 106. The example die 122 is spaced apart from the die 120 on the surface 206 to define the gap 126 between the dies 120, 122. Further, the example dielectric layer 204 is attached to/positioned on the surfaces 128, 130 of the dies 120, 122. For example, the dielectric layer 204 may be in contact with the surfaces 128, 130 of the dies 120, 122. As shown in FIG. 2, the surfaces 128, 130 face away from the semiconductor substrate 106. As such, the dies 120, 122 are positioned between the dielectric layer 204 and the semiconductor substrate 106. In other examples, the dielectric layer 204 may be excluded from the semiconductor package 200 (as described in connection with FIGS. 5A-5E). For example, the package lid 112 may be attached to the surfaces 128, 130 of the dies 120, 122.

The example polymer material 202 fills the gap 126 between the dies 120, 122. In some examples, the polymer material 202 may separate the die 120 from the die 122. For example, the polymer material 202 may be in contact with both the die 120 and the die 122. In other examples, the polymer material 202 may only be in contact with an example side 208 of the die 120. The polymer material 202 extends from an example surface 210 of the die 120 (facing towards the semiconductor substrate 106 and interfacing with the surface 206 of the semiconductor substrate 106) towards the surface 128. As shown in FIG. 2, the polymer material 202 may cover the side 208 of the die 120. In other words, the polymer material 202 may be added along an example surface 212 of the die 120, where the surface 212 is positioned at an angle relative (e.g., not parallel) to the surface 206 of the semiconductor substrate 106.

The example surface 128 of the die 120 is substantially coplanar or flush (e.g., within 100 nm of linear offset and within 5 degrees (°) of angular offset) with the surface 130 of the die 122. Additionally, the example polymer material 202 (e.g., an end of the polymer material 202, a portion of the polymer material 202, etc.) is substantially coplanar with the surface 128 of the die 120. In other words, the surface 128 may define a first plane and an example portion of the polymer material 202 may define a second plane, the first plane substantially coplanar with the second plane. As such, the polymer material 202 may extend to (e.g., reach) the dielectric layer 204 such that the polymer material 202 is in contact with the dielectric layer 204. In other examples, the polymer material 202 may be in contact with the package lid 112 as described in connection with FIG. 5E.

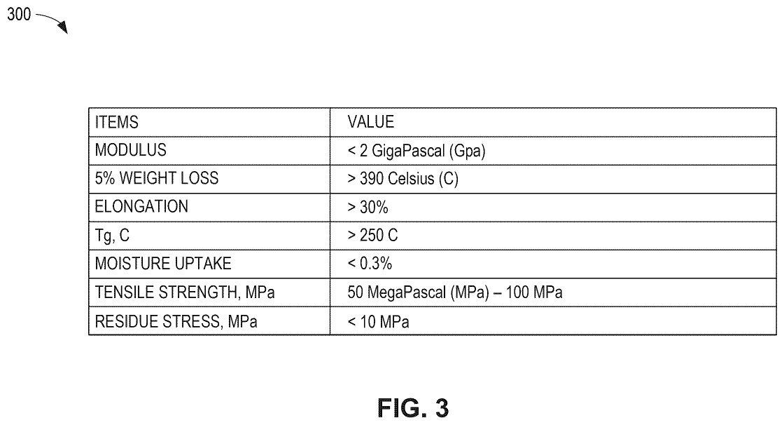

FIG. 3 is a table 300 illustrating example properties that may be associated with the example polymer material 202. In some examples, the polymer material 202 may include a non filler filled polymer based on modified polyimide. In some examples, the polymer material 202 may have a Tg greater than 250 C. The example polymer material 202 may also include a Young's modulus less than 2 Gigapascal (GPa). The example polymer material 202 may also include a residue stress less than 10 MPa which can mitigate water warpage. Additionally, the example polymer material 202 may include any of the properties listed the table 300.

In some examples, the example polymer material 202 may have a relatively high coefficient of thermal expansion (CTE) (e.g., greater than 100 parts per million per degree Centigrade)) (ppm/C°)), which can give rise to stress and/or warpage in the package when facing temperature fluctuations. However, a relatively high CTE is expected to not be a significant risk because the polymer material is located near the top of the package (e.g., adjacent to lid 112). Further, any stress induced by the contraction or expansion of the polymer material 202 may be alleviated based on the thickness/strength of the surrounding structural silicon (e.g., in the package lid 112 and/or the adjacent dies 120, 122). Furthermore, in some examples, the polymer material 202 has a CTE that remains substantially constant as temperature increases from room temperature to 300 C.

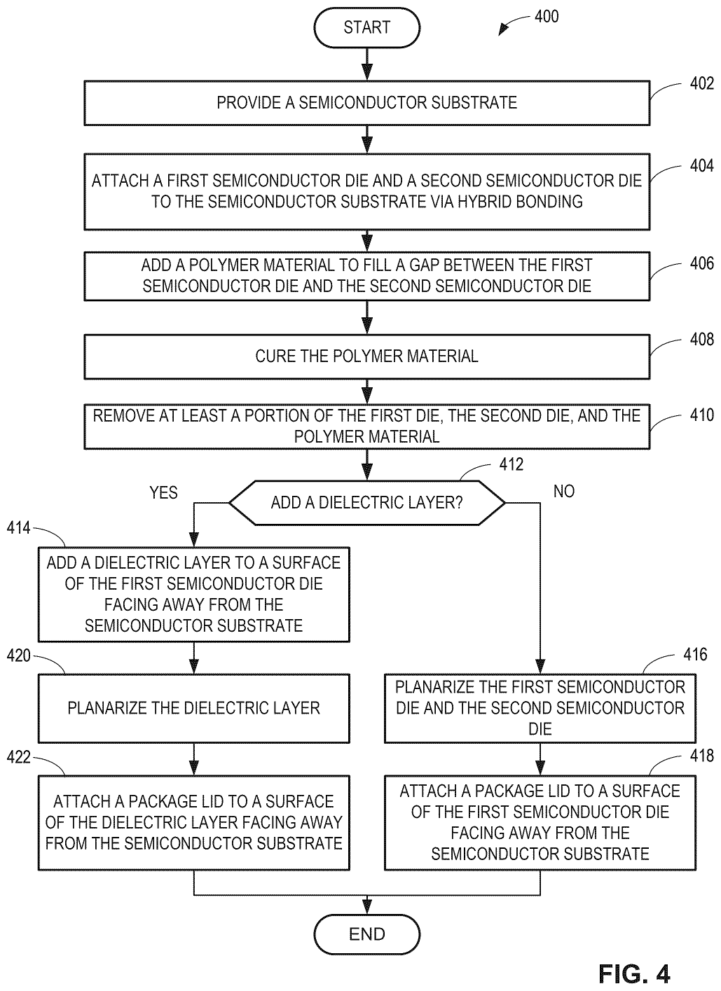

FIG. 4 is a flowchart representative of an example method 400 to produce the example semiconductor package 200 of FIG. 2 and the example semiconductor package 500 of FIG. 5E. FIGS. 5A-5D and 6A-6C represent the example semiconductor package 200 at various stages during the example process described in FIG. 4. FIGS. 5A-5E represent the example semiconductor package 500 at various stages during the example process described in FIG. 4. In some examples, some or all of the operations outlined in the example method of FIG. 4 are performed automatically by fabrication equipment that is programmed to perform the operation. Although the example method of manufacture is described with reference to the flowchart illustrated in FIG. 4, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example.

Turning to FIG. 4, the example process begins at block 402, at which an example semiconductor substrate is provided. As shown in FIG. 5A, the example semiconductor substrate 106 is provided.

At block 404, a first example semiconductor die and a second example semiconductor die are attached to the semiconductor substrate via hybrid bonding. As shown in FIG. 5A, the die 120 and the die 122 are attached to the semiconductor substrate 106 via hybrid bonding (e.g., via the embedded interconnects 124 including the bonding pads 125). Further, the die 120 and the die 122 are spaced apart from one another on the surface 206 of the semiconductor substrate 106. In some examples, only one of the dies 120, 122 may be attached to the semiconductor substrate 106.

At block 406, an example polymer material is added to fill a gap between the first die and the second die. As shown in FIG. 5B, the example polymer material 202 is added to fill the gap 126 between the die 120 and the die 122. The polymer material 202 extends from the surface 210 (facing towards the semiconductor substrate 106) towards the surface 128 (facing away from the semiconductor substrate 106). As such, the polymer material 202 cover(s) the side 208 of the die 120. Further, the example polymer material 202 is added such that the polymer material 202 covers (e.g., overfills the gap 126) the surfaces 128, 130 of the dies 120, 122. In some examples, the polymer material 202 may be deposited on the dies 106, 120, 122 via spin coating.

At block 408, the example polymer material is cured. For example, the polymer material 202 may be cured. In some examples, the polymer material 202 may be ultra-violet (UV) cured, low thermal cured (e.g., at 230° C.), etc.

At block 410, at least a portion of the first die, the second die, and the polymer material is removed. As shown in FIG. 5C, at least a portion of the die 120, the die 122, and the polymer material 202 is removed. As such, the dies 120, 122 may decrease in size. Further, the example polymer material 202 may be removed (e.g., completely removed) from the surfaces 128, 130 of the dies 120, 122. In some examples, the at least a portion of the die 120, the die 122, and the polymer material 202 is removed via thinning (e.g., polishing, grinding, etc.) process. In some examples, the polymer material 202 may not be substantially coplanar to the surfaces 128, 130 after the thinning process based on the nature of the process.

At block 412, it is determined whether to add an example dielectric layer. If an example dielectric layer is to be added, the process proceeds to block 414, as discussed below in connection with FIGS. 6A-6C. If no dielectric layer is to be added, then the process proceeds to block 416. In the example process illustrated by FIGS. 5A-5E, no dielectric layer is to be added. In such examples, the process proceeds to block 416.

At block 416, the first semiconductor die and the second semiconductor die are planarized. As shown in FIG. 5D, the surfaces 128, 130 of the dies 120, 122 are planarized (e.g., polished, smoothed, etc.). In other words, at least a portion of the dies 120, 122 are removed (e.g., flattened) via a CMP process. In some examples, the polymer material 202 is also planarized during this process. Thus, as shown in FIG. 5D, the polymer material 202 may be substantially coplanar with the surfaces 128, 130 of the dies 120, 122 after the CMP process.

At block 418, an example package lid is attached to a surface of the first semiconductor die facing away from the semiconductor substrate. As shown in FIG. 5E, the package lid 112 is attached to the surfaces 128, 130 of the dies 120, 122. The example polymer material 202 is enclosed by the semiconductor substrate 106, the die 120, the die 122, and the package lid 112. Additionally, the polymer material 202 is in contact with the semiconductor substrate 106, the die 120, the die 122, and the package lid 112. In some examples, the package lid 112 may be hybrid bonded to the dies 120, 122. Then, the process ends.

Returning to block 412, if it is determined that an example dielectric layer is to be added, then the process proceeds to block 414 with the subsequent stage(s) of fabrication represented by FIGS. 6A-6C. At block 414, an example dielectric layer is added to a surface of the first semiconductor die facing away from the semiconductor substrate. As shown in FIG. 6A, the example dielectric layer 204 is added to the surfaces 128, 130 of the dies 120, 122 facing away from the semiconductor substrate 106.

At block 420, the dielectric layer is planarized. As shown in FIG. 6B, the example dielectric layer 204 is planarized. In other words, at least a portion of the example dielectric layer 204 is removed via a CMP process.

At block 422, an example package lid is attached to a surface of the dielectric layer facing away from the semiconductor substrate. As shown in FIG. 6C, the example package lid 112 is attached to an example surface 502 of the dielectric layer 204. The example surface 502 of the dielectric layer 204 is facing away from the semiconductor substrate 106. In the example semiconductor package 200, the polymer material 202 is in contact with the dielectric layer 204. In some examples, the package lid 112 may be fusion bonded to the dielectric layer 204. Then, the process ends.

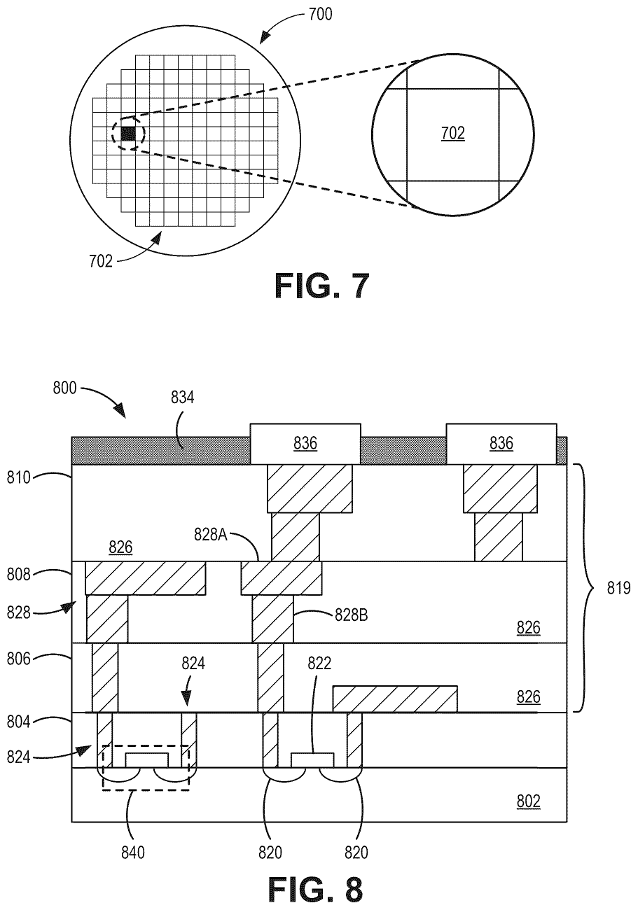

The example semiconductor packages 200, 500 disclosed herein may be included in any suitable electronic component. FIGS. 7-10 illustrate various examples of apparatus that may include or be included in the semiconductor packages 200, 500 disclosed herein.

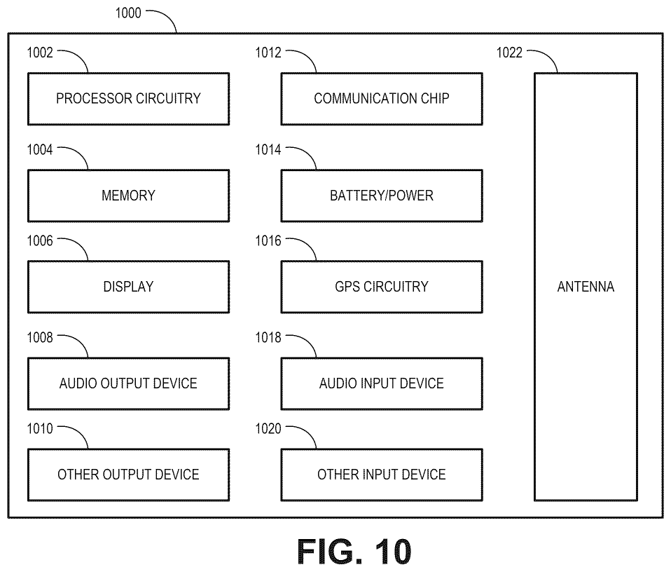

FIG. 7 is a top view of a wafer 700 and dies 702 that may be included in the IC package 100 of FIG. 1 and/or the IC packages 200, 500 of FIGS. 2 and 5E (e.g., as any suitable ones of the dies 106, 108, 120, 122). The wafer 700 includes semiconductor material and one or more dies 702 having circuitry. Each of the dies 702 may be a repeating unit of a semiconductor product. After the fabrication of the semiconductor product is complete, the wafer 700 may undergo a singulation process in which the dies 702 are separated from one another to provide discrete “chips.” The die 702 includes one or more transistors (e.g., some of the transistors 840 of FIG. 8, discussed below), supporting circuitry to route electrical signals to the transistors, passive components (e.g., traces, resistors, capacitors, inductors, and/or other circuitry), and/or any other components. In some examples, the die 702 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry or electronics. Multiple ones of these devices may be combined on a single die 702. For example, a memory array of multiple memory circuits may be formed on a same die 702 as programmable circuitry (e.g., the processor circuitry 1002 of FIG. 10) and/or other logic circuitry. Such memory may store information for use by the programmable circuitry. The example IC package 100 of FIG. 1 disclosed herein may be manufactured using a die-to-wafer assembly technique in which some dies are attached to a wafer 700 that include others of the dies, and the wafer 700 is subsequently singulated.

FIG. 8 is a cross-sectional side view of an IC device 800 that may include the example IC package 100 and/or the IC packages 200, 500 of FIGS. 2 and 5E (e.g., in any one of the dies 106, 108, 120, 122). One or more of the IC devices 800 may be included in one or more dies 702 (FIG. 7). The IC device 800 may be formed on a die substrate 802 (e.g., the wafer 700 of FIG. 7) and may be included in a die (e.g., the die 702 of FIG. 7). The die substrate 802 may be a semiconductor substrate including semiconductor materials including, for example, n-type or p-type materials systems (or a combination of both). The die substrate 802 may include, for example, a crystalline substrate formed using a bulk silicon or a silicon-on-insulator (SOI) substructure. In some examples, the die substrate 802 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 802. Although a few examples of materials from which the die substrate 802 may be formed are described here, any material that may serve as a foundation for an IC device 800 may be used. The die substrate 802 may be part of a singulated die (e.g., the dies 702 of FIG. 7) or a wafer (e.g., the wafer 700 of FIG. 7).

The IC device 800 may include one or more device layers 804 disposed on and/or above the die substrate 802. The device layer 804 may include features of one or more transistors 840 (e.g., metal oxide semiconductor field-effect transistors (MOSFETs)) formed on the die substrate 802. The device layer 804 may include, for example, one or more source and/or drain (S/D) regions 820, a gate 822 to control current flow between the S/D regions 820, and one or more S/D contacts 824 to route electrical signals to/from the S/D regions 820. The transistors 840 may include additional features not depicted for the sake of clarity, such as device isolation regions, gate contacts, and the like. The transistors 840 are not limited to the type and configuration depicted in FIG. 8 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 840 may include a gate 822 including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and/or zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and/or lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 840 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included, such as a barrier layer. For a PMOS transistor, metals that may be used for the gate electrode include, but are not limited to, ruthenium, palladium, platinum, cobalt, nickel, conductive metal oxides (e.g., ruthenium oxide), and/or any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and/or aluminum carbide), and/or any of the metals discussed above with reference to a PMOS transistor (e.g., for work function tuning).

In some examples, when viewed as a cross-section of the transistor 840 along the source-channel-drain direction, the gate electrode may include a U-shaped structure that includes a bottom portion substantially parallel to the surface of the die substrate 802 and two sidewall portions that are substantially perpendicular to the top surface of the die substrate 802. In other examples, at least one of the metal layers that form the gate electrode may be a planar layer that is substantially parallel to the top surface of the die substrate 802 and does not include sidewall portions substantially perpendicular to the top surface of the die substrate 802. In other examples, the gate electrode may include a combination of U-shaped structures and/or planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and/or silicon oxynitride. Processes for forming sidewall spacers are well known in the art and generally include deposition and etching process operations. In some examples, a plurality of spacer pairs may be used; for instance, two pairs, three pairs, or four pairs of sidewall spacers may be formed on opposing sides of the gate stack.

The S/D regions 820 may be formed within the die substrate 802 adjacent to the gate 822 of corresponding transistor(s) 840. The S/D regions 820 may be formed using an implantation/diffusion process or an etching/deposition process, for example. In the former process, dopants such as boron, aluminum, antimony, phosphorous, or arsenic may be ion-implanted into the die substrate 802 to form the S/D regions 820. An annealing process that activates the dopants and causes them to diffuse farther into the die substrate 802 may follow the ion-implantation process. In the latter process, the die substrate 802 may first be etched to form recesses at the locations of the S/D regions 820. An epitaxial deposition process may then be carried out to fill the recesses with material that is used to fabricate the S/D regions 820. In some implementations, the S/D regions 820 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 820 may be formed using one or more alternate semiconductor materials such as germanium or a group III-V material or alloy. In further examples, one or more layers of metal and/or metal alloys may be used to form the S/D regions 820.

Electrical signals, such as power and/or input/output (I/O) signals, may be routed to and/or from the devices (e.g., transistors 840) of the device layer 804 through one or more interconnect layers disposed on the device layer 804 (illustrated in FIG. 8 as interconnect layers 806-810). For example, electrically conductive features of the device layer 804 (e.g., the gate 822 and the S/D contacts 824) may be electrically coupled with the interconnect structures 828 of the interconnect layers 806-810. The one or more interconnect layers 806-810 may form a metallization stack (also referred to as an “ILD stack”) 819 of the IC device 800.

The interconnect structures 828 may be arranged within the interconnect layers 806-810 to route electrical signals according to a wide variety of designs (in particular, the arrangement is not limited to the particular configuration of interconnect structures 828 depicted in FIG. 8). Although a particular number of interconnect layers 806-810 is depicted in FIG. 8, examples of the present disclosure include IC devices having more or fewer interconnect layers than depicted.

In some examples, the interconnect structures 828 may include lines 828a and/or vias 828b filled with an electrically conductive material such as a metal. The lines 828a may be arranged to route electrical signals in a direction of a plane that is substantially parallel with a surface of the die substrate 802 upon which the device layer 804 is formed. For example, the lines 828a may route electrical signals in a direction in and/or out of the page from the perspective of FIG. 8. The vias 828b may be arranged to route electrical signals in a direction of a plane that is substantially perpendicular to the surface of the die substrate 802 upon which the device layer 804 is formed. In some examples, the vias 828b may electrically couple lines 828a of different interconnect layers 806-810 together.

The interconnect layers 806-810 may include a dielectric material 826 disposed between the interconnect structures 828, as shown in FIG. 8. In some examples, the dielectric material 826 disposed between the interconnect structures 828 in different ones of the interconnect layers 806-810 may have different compositions; in other examples, the composition of the dielectric material 826 between different interconnect layers 806-810 may be the same.

A first interconnect layer 806 (referred to as Metal 1 or “M1”) may be formed directly on the device layer 804. In some examples, the first interconnect layer 806 may include lines 828a and/or vias 828b, as shown. The lines 828a of the first interconnect layer 806 may be coupled with contacts (e.g., the S/D contacts 824) of the device layer 804.

A second interconnect layer 808 (referred to as Metal 2 or “M2”) may be formed directly on the first interconnect layer 806. In some examples, the second interconnect layer 808 may include vias 828b to couple the lines 828a of the second interconnect layer 808 with the lines 828a of the first interconnect layer 806. Although the lines 828a and the vias 828b are structurally delineated with a line within each interconnect layer (e.g., within the second interconnect layer 808) for the sake of clarity, the lines 828a and the vias 828b may be structurally and/or materially contiguous (e.g., simultaneously filled during a dual-damascene process) in some examples.

A third interconnect layer 810 (referred to as Metal 3 or “M3”) (and additional interconnect layers, as desired) may be formed in succession on the second interconnect layer 808 according to similar techniques and/or configurations described in connection with the second interconnect layer 808 or the first interconnect layer 806. In some examples, the interconnect layers that are “higher up” in the metallization stack 819 in the IC device 800 (i.e., further away from the device layer 804) may be thicker.

The IC device 800 may include a solder resist material 834 (e.g., polyimide or similar material) and one or more conductive contacts 836 formed on the interconnect layers 806-810. In FIG. 8, the conductive contacts 836 are illustrated as taking the form of bond pads. The conductive contacts 836 may be electrically coupled with the interconnect structures 828 and configured to route the electrical signals of the transistor(s) 840 to other external devices. For example, solder bonds may be formed on the one or more conductive contacts 836 to mechanically and/or electrically couple a chip including the IC device 800 with another component (e.g., a circuit board). The IC device 800 may include additional or alternate structures to route the electrical signals from the interconnect layers 806-810; for example, the conductive contacts 836 may include other analogous features (e.g., posts) that route the electrical signals to external components.

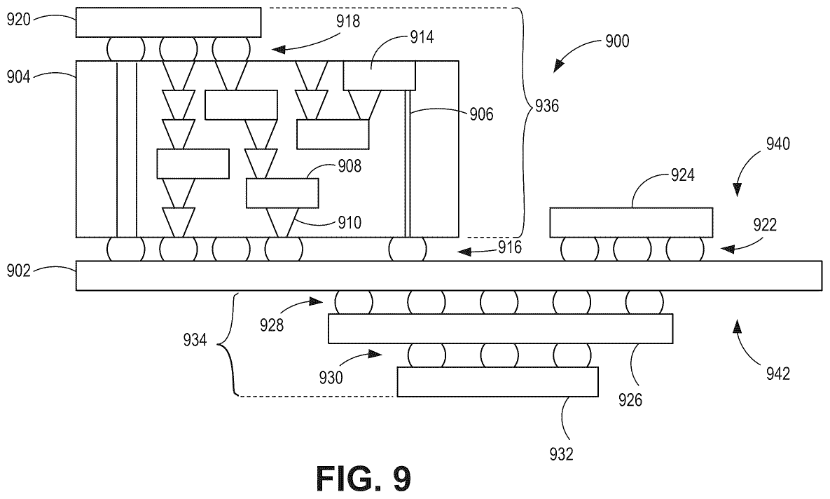

FIG. 9 is a cross-sectional side view of an IC device assembly 900 that may include the IC package 100 of FIG. 1 and/or the IC packages 200, 500 of FIGS. 2 and 5E disclosed herein. In some examples, the IC device assembly corresponds to the IC package 100 of FIG. 1 and/or the IC packages 200, 500 of FIGS. 2 and 5E. The IC device assembly 900 includes a number of components disposed on a circuit board 902 (which may be, for example, a motherboard). The IC device assembly 900 includes components disposed on a first face 940 of the circuit board 902 and an opposing second face 942 of the circuit board 902; generally, components may be disposed on one or both faces 940 and 942. Any of the IC packages discussed below with reference to the IC device assembly 900 may take the form of the example IC package 100 of FIG. 1 and/or the IC packages 200, 500 of FIGS. 2 and 5E.

In some examples, the circuit board 902 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 902. In other examples, the circuit board 902 may be a non-PCB substrate.

The IC device assembly 900 illustrated in FIG. 9 includes a package-on-interposer structure 936 coupled to the first face 940 of the circuit board 902 by coupling components 916. The coupling components 916 may electrically and mechanically couple the package-on-interposer structure 936 to the circuit board 902, and may include solder balls (as shown in FIG. 9), male and female portions of a socket, an adhesive, an underfill material, and/or any other suitable electrical and/or mechanical coupling structure.

The package-on-interposer structure 936 may include an IC package 920 coupled to an interposer 904 by coupling components 918. The coupling components 918 may take any suitable form for the application, such as the forms discussed above with reference to the coupling components 916. Although a single IC package 920 is shown in FIG. 9, multiple IC packages may be coupled to the interposer 904; indeed, additional interposers may be coupled to the interposer 904. The interposer 904 may provide an intervening substrate used to bridge the circuit board 902 and the IC package 920. The IC package 920 may be or include, for example, a die (the die 702 of FIG. 7), an IC device (e.g., the IC device 800 of FIG. 8), or any other suitable component. Generally, the interposer 904 may spread a connection to a wider pitch or reroute a connection to a different connection. For example, the interposer 904 may couple the IC package 920 (e.g., a die) to a set of BGA conductive contacts of the coupling components 916 for coupling to the circuit board 902. In the example illustrated in FIG. 9, the IC package 920 and the circuit board 902 are attached to opposing sides of the interposer 904; in other examples, the IC package 920 and the circuit board 902 may be attached to a same side of the interposer 904. In some examples, three or more components may be interconnected by way of the interposer 904.

In some examples, the interposer 904 may be formed as a PCB, including multiple metal layers separated from one another by layers of dielectric material and interconnected by electrically conductive vias. In some examples, the interposer 904 may be formed of an epoxy resin, a fiberglass-reinforced epoxy resin, an epoxy resin with inorganic fillers, a ceramic material, or a polymer material such as polyimide. In some examples, the interposer 904 may be formed of alternate rigid or flexible materials that may include the same materials described above for use in a semiconductor substrate, such as silicon, germanium, and other group III-V and group IV materials. The interposer 904 may include metal interconnects 908 and vias 910, including but not limited to through-silicon vias (TSVs) 906. The interposer 904 may further include embedded devices 914, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 904. The package-on-interposer structure 936 may take the form of any of the package-on-interposer structures known in the art.

The IC device assembly 900 may include an IC package 924 coupled to the first face 940 of the circuit board 902 by coupling components 922. The coupling components 922 may take the form of any of the examples discussed above with reference to the coupling components 916, and the IC package 924 may take the form of any of the examples discussed above with reference to the IC package 920.

The IC device assembly 900 illustrated in FIG. 9 includes a package-on-package structure 934 coupled to the second face 942 of the circuit board 902 by coupling components 928. The package-on-package structure 934 may include a first IC package 926 and a second IC package 932 coupled together by coupling components 930 such that the first IC package 926 is disposed between the circuit board 902 and the second IC package 932. The coupling components 928, 930 may take the form of any of the examples of the coupling components 916 discussed above, and the IC packages 926, 932 may take the form of any of the examples of the IC package 920 discussed above. The package-on-package structure 934 may be configured in accordance with any of the package-on-package structures known in the art.

FIG. 10 is a block diagram of an example electrical device 1000 that may include one or more of the example IC packages 100, 200, 500 disclosed herein. For example, any suitable ones of the components of the electrical device 1000 may include one or more of the device assemblies 900, IC devices 800, or dies 702 disclosed herein, and may be arranged in the example IC package 100 of FIG. 1 and/or the semiconductor packages 200, 500 of FIGS. 2 and 5E. A number of components are illustrated in FIG. 10 as included in the electrical device 1000, but any one or more of these components may be omitted or duplicated, as suitable for the application. In some examples, some or all of the components included in the electrical device 1000 may be attached to one or more motherboards. In some examples, some or all of these components are fabricated onto a single system-on-a-chip (SoC) die.

Additionally, in various examples, the electrical device 1000 may not include one or more of the components illustrated in FIG. 10, but the electrical device 1000 may include interface circuitry for coupling to the one or more components. For example, the electrical device 1000 may not include a display 1006, but may include display interface circuitry (e.g., a connector and driver circuitry) to which a display 1006 may be coupled. In another set of examples, the electrical device 1000 may not include an audio input device 1018 (e.g., microphone) or an audio output device 1008 (e.g., a speaker, a headset, earbuds, etc.), but may include audio input or output device interface circuitry (e.g., connectors and supporting circuitry) to which an audio input device 1018 or audio output device 1008 may be coupled.

The electrical device 1000 may include programmable circuitry 1002 (e.g., one or more processing devices). The programmable circuitry 1002 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1000 may include a memory 1004, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1004 may include memory that shares a die with the programmable circuitry 1002. This memory may be used as cache memory and may include embedded dynamic random access memory (eDRAM) or spin transfer torque magnetic random access memory (STT-MRAM).

In some examples, the electrical device 1000 may include a communication chip 1012 (e.g., one or more communication chips). For example, the communication chip 1012 may be configured for managing wireless communications for the transfer of data to and from the electrical device 1000. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 1012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1012 may operate in accordance with other wireless protocols in other examples. The electrical device 1000 may include an antenna 1022 to facilitate wireless communications and/or to receive other wireless communications (such as AM or FM radio transmissions).

In some examples, the communication chip 1012 may manage wired communications, such as electrical, optical, or any other suitable communication protocols (e.g., the Ethernet). As noted above, the communication chip 1012 may include multiple communication chips. For instance, a first communication chip 1012 may be dedicated to shorter-range wireless communications such as Wi-Fi or Bluetooth, and a second communication chip 1012 may be dedicated to longer-range wireless communications such as global positioning system (GPS), EDGE, GPRS, CDMA, WiMAX, LTE, EV-DO, or others. In some examples, a first communication chip 1012 may be dedicated to wireless communications, and a second communication chip 1012 may be dedicated to wired communications.

The electrical device 1000 may include battery/power circuitry 1014. The battery/power circuitry 1014 may include one or more energy storage devices (e.g., batteries or capacitors) and/or circuitry for coupling components of the electrical device 1000 to an energy source separate from the electrical device 1000 (e.g., AC line power).

The electrical device 1000 may include a display 1006 (or corresponding interface circuitry, as discussed above). The display 1006 may include any visual indicators, such as a heads-up display, a computer monitor, a projector, a touchscreen display, a liquid crystal display (LCD), a light-emitting diode display, or a flat panel display.

The electrical device 1000 may include an audio output device 1008 (or corresponding interface circuitry, as discussed above). The audio output device 1008 may include any device that generates an audible indicator, such as speakers, headsets, or earbuds.

The electrical device 1000 may include an audio input device 1018 (or corresponding interface circuitry, as discussed above). The audio input device 1018 may include any device that generates a signal representative of a sound, such as microphones, microphone arrays, or digital instruments (e.g., instruments having a musical instrument digital interface (MIDI) output).

The electrical device 1000 may include GPS circuitry 1016. The GPS circuitry 1016 may be in communication with a satellite-based system and may receive a location of the electrical device 1000, as known in the art.

The electrical device 1000 may include any other output device 1010 (or corresponding interface circuitry, as discussed above). Examples of the other output device 1010 may include an audio codec, a video codec, a printer, a wired or wireless transmitter for providing information to other devices, or an additional storage device.

The electrical device 1000 may include any other input device 1020 (or corresponding interface circuitry, as discussed above). Examples of the other input device 1020 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1000 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 1000 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that fill the gaps between semiconductor dies of a semiconductor package with a polymer material (e.g., organic material). In disclosed examples, the liquid form of such a polymer material can conform directly to the surfaces of the dies and extend into a gap between the dies without first needing to thin these surfaces. That is, known techniques based on an oxide fill typically cannot reliably deposit the oxide all the way down to the bottom of the depth of the gap defined by a full thickness of the dies, which is why the dies first undergo a thinning process. Further, applying a polymer material between the dies before the thinning process provides structural integrity to the assembly to reduce any cracks and/or chips caused when the dies (along with the polymer material) undergo a thinning process. Further, disclosed examples utilize an example polymer material with a high Tg (e.g., greater than 250 Celsius (C)) to withstand subsequent high temperature processes (e.g., fusion bonding of a package lid).

Example 1 includes an integrated (IC) package comprising a semiconductor substrate, a semiconductor die positioned on the semiconductor substrate, and a polymer material in contact with a side of the semiconductor die, the polymer material extending from a first surface of the semiconductor die towards a second surface of the semiconductor die, the first surface of the semiconductor die facing towards the semiconductor substrate and the second surface of the semiconductor die facing away from the semiconductor substrate.

Example 2 includes the IC package of example 1, further including a dielectric layer in contact with the second surface of the semiconductor die.

Example 3 includes the IC package of any one of examples 1 or 2, wherein the semiconductor die is hybrid bonded to the semiconductor substrate.

Example 4 includes the IC package of any one of examples 1-3, wherein the second surface of the semiconductor die defines a first plane, and a portion of the polymer material defines a second plane, the second plane substantially coplanar with the first plane.

Example 5 includes the IC package of any one of examples 1-4, wherein the polymer material covers the side of the semiconductor die.

Example 6 includes the IC package of any one of examples 1-5, wherein the polymer material includes a Young's modulus less than 2 gigapascal (GPa).

Example 7 includes the IC package of any one of examples 1-6, wherein the semiconductor die is a first semiconductor die and the IC package further includes a second semiconductor die positioned on the semiconductor substrate adjacent the first semiconductor die, the polymer material separating the first semiconductor die from the second semiconductor die.

Example 8 includes the IC package of example 7, further including a package lid attached to the second surface of the first semiconductor die, the polymer material enclosed by the semiconductor substrate, the first semiconductor die, the second semiconductor die, and the package lid.

Example 9 includes the IC package of example 8, wherein the polymer material is in contact with the semiconductor substrate, the first semiconductor die, the second semiconductor die, and the package lid.

Example 10 includes an apparatus comprising a semiconductor substrate, a first semiconductor die bonded to a first surface of the semiconductor substrate, a second semiconductor die bonded to the first surface of the semiconductor substrate, and a material including nitrogen, oxygen, and carbon, the material filling a gap between the first semiconductor die and the second semiconductor die.

Example 11 includes the apparatus of example 10, wherein the first semiconductor die is hybrid bonded to the semiconductor substrate and the second semiconductor die is hybrid bonded to the semiconductor substrate.

Example 12 includes the apparatus of any one of examples 10 or 11, wherein the first semiconductor die has a first surface facing away from the semiconductor substrate and the second semiconductor die has a second surface facing away from the semiconductor substrate, the first surface substantially coplanar to the second surface, an end of the material substantially coplanar to the first surface.

Example 13 includes the apparatus of any one of examples 10-12, further including a package lid positioned on the first semiconductor die and on the second semiconductor die, the second semiconductor die positioned between the package lid and the first semiconductor die, the material in contact with the package lid.

Example 14 includes the apparatus of any one of examples 10-13, wherein the material includes a Young's modulus less than 2 gigapascal (GPa).

Example 15 includes a method comprising providing a semiconductor substrate, hybrid bonding a semiconductor die to the semiconductor substrate, and adding a polymer material along a first surface of the semiconductor die, the first surface of the semiconductor die positioned at an angle relative to a second surface of the semiconductor die, the second surface of the semiconductor die facing towards the semiconductor substrate.

Example 16 includes the method of example 15, further including attaching a package lid to a third surface of the semiconductor die, the third surface opposite the second surface, the polymer material in contact with the package lid.

Example 17 includes the method of any one of examples 15 or 16, further including adding a dielectric layer to a third surface of the semiconductor die, the third surface facing away from the semiconductor substrate, the polymer material in contact with the dielectric layer.

Example 18 includes the method of any one of examples 15-17, wherein the semiconductor die is a first semiconductor die and the method further includes attaching a second semiconductor die to the semiconductor substrate, the second semiconductor die spaced apart from the first semiconductor die, the polymer material in contact with both the first semiconductor die and the second semiconductor die.

Example 19 includes the method of example 18, further including curing the polymer material.

Example 20 includes the method of any one of examples 18 or 19, further including removing at least a portion of the second semiconductor die, the first semiconductor die, and the polymer material in a thinning process, the polymer material added prior to the thinning process.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An integrated (IC) package comprising:
a semiconductor substrate;
a semiconductor die positioned on the semiconductor substrate; and
a polymer material in contact with a side of the semiconductor die, the polymer material extending from a first surface of the semiconductor die towards a second surface of the semiconductor die, the first surface of the semiconductor die facing towards the semiconductor substrate and the second surface of the semiconductor die facing away from the semiconductor substrate.

2. The IC package of claim 1, further including a dielectric layer in contact with the second surface of the semiconductor die.

3. The IC package of claim 1, wherein the semiconductor die is hybrid bonded to the semiconductor substrate.

4. The IC package of claim 1, wherein the second surface of the semiconductor die defines a first plane, and a portion of the polymer material defines a second plane, the second plane substantially coplanar with the first plane.

5. The IC package of claim 1, wherein the polymer material covers the side of the semiconductor die.

6. The IC package of claim 1, wherein the polymer material includes a Young's modulus less than 2 gigapascal (GPa).

7. The IC package of claim 1, wherein the semiconductor die is a first semiconductor die and the IC package further includes a second semiconductor die positioned on the semiconductor substrate adjacent the first semiconductor die, the polymer material separating the first semiconductor die from the second semiconductor die.

8. The IC package of claim 7, further including a package lid attached to the second surface of the first semiconductor die, the polymer material enclosed by the semiconductor substrate, the first semiconductor die, the second semiconductor die, and the package lid.

9. The IC package of claim 8, wherein the polymer material is in contact with the semiconductor substrate, the first semiconductor die, the second semiconductor die, and the package lid.

10. An apparatus comprising:
a semiconductor substrate;
a first semiconductor die bonded to a first surface of the semiconductor substrate;
a second semiconductor die bonded to the first surface of the semiconductor substrate; and
a material including nitrogen, oxygen, and carbon, the material filling a gap between the first semiconductor die and the second semiconductor die.

11. The apparatus of claim 10, wherein the first semiconductor die is hybrid bonded to the semiconductor substrate and the second semiconductor die is hybrid bonded to the semiconductor substrate.

12. The apparatus of claim 10, wherein the first semiconductor die has a first surface facing away from the semiconductor substrate and the second semiconductor die has a second surface facing away from the semiconductor substrate, the first surface substantially coplanar to the second surface, an end of the material substantially coplanar to the first surface.

13. The apparatus of claim 10, further including a package lid positioned on the first semiconductor die and on the second semiconductor die, the second semiconductor die positioned between the package lid and the first semiconductor die, the material in contact with the package lid.

14. The apparatus of claim 10, wherein the material includes a Young's modulus less than 2 gigapascal (GPa).

15. A method comprising:
providing a semiconductor substrate;
hybrid bonding a semiconductor die to the semiconductor substrate; and
adding a polymer material along a first surface of the semiconductor die, the first surface of the semiconductor die positioned at an angle relative to a second surface of the semiconductor die, the second surface of the semiconductor die facing towards the semiconductor substrate.

16. The method of claim 15, further including attaching a package lid to a third surface of the semiconductor die, the third surface opposite the second surface, the polymer material in contact with the package lid.

17. The method of claim 15, further including adding a dielectric layer to a third surface of the semiconductor die, the third surface facing away from the semiconductor substrate, the polymer material in contact with the dielectric layer.

18. The method of claim 15, wherein the semiconductor die is a first semiconductor die and the method further includes attaching a second semiconductor die to the semiconductor substrate, the second semiconductor die spaced apart from the first semiconductor die, the polymer material in contact with both the first semiconductor die and the second semiconductor die

19. The method of claim 18, further including curing the polymer material.

20. The method of claim 18, further including removing at least a portion of the second semiconductor die, the first semiconductor die, and the polymer material in a thinning process, the polymer material added prior to the thinning process.
